(19) United States
(12) Patent Application Publication
(10) Pub. No.: US 2025/0129479 A1
(43) Pub. Date: Apr. 24, 2025

(54) FILM-FORMING METHOD AND FILM-FORMING SYSTEM

(71) Applicant: Tokyo Electron Limited, Tokyo (JP)

(72) Inventor: Hitoshi KATO, Iwate (JP)

(21) Appl. No.: 18/907,967

(22) Filed: Oct. 7, 2024

(30) Foreign Application Priority Data
Oct. 24, 2023 (JP) 2023-182601

(51) Int. Cl. C23C 16/458; C23C 16/455; C23C 16/52; H01L 21/02

(52) U.S. Cl. CPC C23C 16/4584; C23C 16/45544; C23C 16/52; H01L 21/02164; H01L 21/02271

(57) ABSTRACT

A film-forming method for forming a film on a substrate, the film-forming method includes: (A) forming a film on a substrate by a first film-forming apparatus, and (B) moving the substrate provided with the film formed in the (A) to a second film-forming apparatus different from the first film-forming apparatus and forming a film over the substrate by the second film-forming apparatus. In the (B), the substrate is rotated inside a process chamber, one of the substrate or a nozzle gas discharge mechanism is moved relative to another of the substrate or the nozzle gas discharge mechanism such that a discharge hole of the nozzle gas discharge mechanism passes over a center of the substrate, and a processing gas is discharged from the discharge hole toward the substrate, thereby adjusting a film thickness of the film to be formed over the substrate.

### CROSS-REFERENCE TO RELATED APPLICATIONS

The present application is based on and claims priority to Japanese Patent Application No. 2023-182601 filed on Oct. 24, 2023, the entire contents of which are hereby incorporated by reference.

### BACKGROUND

### 1. Field of the Invention

The present disclosure relates to a film-forming method and a film-forming system.

### 2. Description of the Related Art

Known film-forming apparatuses are configured to rotate multiple wafers (substrates) held on a susceptor and supply multiple types of processing gases over the substrates, thereby forming desired films on the surfaces of the substrates. In recent years, in accordance with miniaturization and increasing performance of semiconductor devices, it is desirable to provide a film-forming method of forming a thin film having excellent in-plane uniformity in terms of film thickness.

For example, Japanese Patent Application Publication No. 2018-62703 discloses a film-forming apparatus in which gas supplies are disposed above, and correspondingly to, two horizontally aligned substrates in a process chamber. This film-forming apparatus is configured to rotate each of the gas supplies about a shaft between the two substrates and discharge gas to the individual substrates, thereby forming films.

### SUMMARY

One aspect of the present disclosure provides a film-forming method for forming a film on a substrate. The film-forming method includes: (A) forming a film on the substrate by a first film-forming apparatus, and (B) moving the substrate provided with the film formed in (A) to a second film-forming apparatus different from the first film-forming apparatus and forming a film over the substrate by the second film-forming apparatus. In (B), the substrate is rotated inside a process chamber, one of the substrate or a nozzle gas discharge mechanism is moved relative to another of the substrate or the nozzle gas discharge mechanism such that discharge holes of the nozzle gas discharge mechanism pass over a center of the substrate, and a gas is discharged from the discharge hole toward the substrate, thereby adjusting a film thickness of the film to be formed on the substrate.

### BRIEF DESCRIPTION OF THE DRAWINGS

FIG. 1 is a block diagram illustrating a film-forming system according to an embodiment of the present disclosure;

FIG. 2 is a schematic cross-sectional diagram illustrating one example of a first film-forming apparatus of the film-forming system;

FIG. 3A is a schematic diagram illustrating a state in which a flat film is formed on a substrate;

FIG. 3B is a schematic diagram illustrating a state in which a recessed film is formed on a substrate;

FIG. 4 is a schematic cross-sectional diagram illustrating one example of a second film-forming apparatus of a film-forming system;

FIG. 5 is a schematic cross-sectional diagram taken along a diagonal line of a process chamber in the film-forming apparatus of FIG. 4;

FIG. 6A is a schematic cross-sectional diagram illustrating a front end of a first nozzle gas discharge mechanism;

FIG. 6B is a schematic plan diagram illustrating a discharger of a first head;

FIG. 7A is a schematic cross-sectional diagram illustrating a front end of a second nozzle gas discharge mechanism;

FIG. 7B is a schematic plan diagram illustrating a discharger of a second head;

FIG. 8 is a schematic plan diagram for describing a swing speed of the first nozzle gas discharge mechanism;

FIG. 9A is a schematic plan diagram illustrating a first movement example of the first nozzle gas discharge mechanism and the second nozzle gas discharge mechanism in partial film formation;

FIG. 9B is a schematic plan diagram illustrating a second movement example of the first nozzle gas discharge mechanism and the second nozzle gas discharge mechanism in partial film formation;

FIG. 10A is a schematic side diagram illustrating a first film-forming step in which an overall film formation is performed;

FIG. 10B is a schematic side diagram illustrating a second film-forming step in which a partial film formation is performed;

FIG. 11A is a flowchart illustrating an example of the film-forming method according to an embodiment;

FIG. 11B is a flowchart illustrating an example of processing performed in the second film-forming apparatus;

FIGS. 12A to 12F are diagrams illustrating target shapes of a film formed on a substrate; and

FIG. 13 is a plan diagram illustrating a film-forming apparatus according to a modified example of the embodiment of the present disclosure.

### DETAILED DESCRIPTION OF THE DISCLOSURE

The present disclosure provides a technique capable of readily forming a film to have a desired film thickness with high accuracy.

Hereinafter, embodiments of the present disclosure will be described with reference to the drawings. In the drawings, the same components may be denoted by the same reference symbols, and duplicate description thereof may be omitted.

### Configuration of Film-Forming System SYS

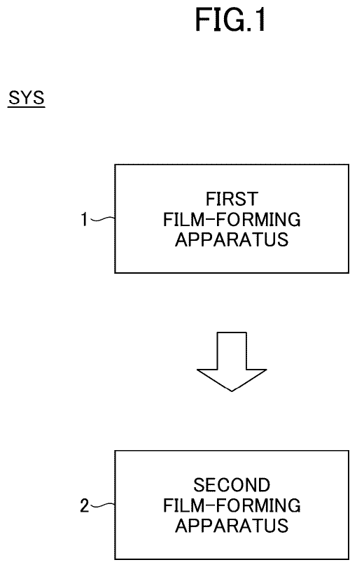

As illustrated in FIG. 1, a film-forming system SYS according to one embodiment includes a first film-forming apparatus 1 and a second film-forming apparatus 2. In the film-forming system SYS, after a film is formed on a surface of a substrate W in the first film-forming apparatus 1, the substrate W is moved from the first film-forming apparatus 1 to the second film-forming apparatus 2, and a film is formed again on the surface of the substrate W by the second film-forming apparatus 2, thereby forming a film having a target shape on the substrate W. That is, the first film-forming apparatus 1 is an apparatus for forming a main film on the substrate W, and the second film-forming apparatus 2 is an apparatus for adjusting a film thickness of a film to be formed over the substrate W.

A semiconductor wafer such as a silicon semiconductor, a compound semiconductor, or an oxide semiconductor is exemplified as the substrate W to be subjected to film formation. The substrate W may have projecting and recessed patterns such as trenches and vias. The film-forming system SYS may be configured to measure a film state (in-plane film thickness, film shape, etc.) of the substrate W via a measuring device while the substrate W is moved from the first film-forming apparatus 1 to the second film-forming apparatus 2.

The first film-forming apparatus 1 is not particularly limited, and can be, for example, a batch type apparatus that accommodates a plurality of substrates W and simultaneously forms a film on each substrate W. Alternatively, the first film-forming apparatus 1 may be a single-wafer type apparatus that accommodates and forms a film on each substrate W. On the other hand, the second film-forming apparatus 2 is preferably an apparatus that can partially form a film on a portion where the film formed on the substrate W is thin. Hereinafter, an example of the first film-forming apparatus 1 and the second film-forming apparatus 2 of the film-forming system SYS will be described.

### Configuration of First Film-Forming Apparatus 1

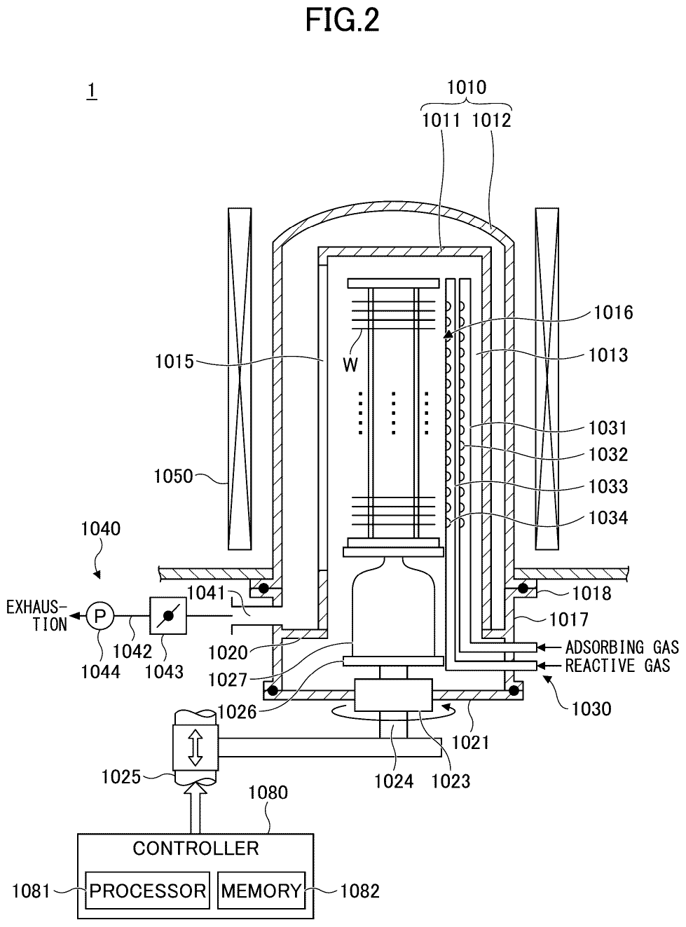

The first film-forming apparatus 1 can be, for example, a vertical heat treatment apparatus as illustrated in FIG. 2 as a batch type apparatus. The first film-forming apparatus 1 performs film formation through atomic layer deposition (ALD) or molecular layer deposition (MLD) in which a substrate W is heated to form a film. The first film-forming apparatus 1 includes a process chamber 1010 that contains a plurality of substrates W, a gas supply 1030 that supplies gas into the process chamber 1010, a gas exhauster 1040 that discharges the gas in the process chamber 1010, a heater 1050 that heats the process chamber 1010, and a controller 1080 that controls each configuration of the apparatus. The first film-forming apparatus 1 may be configured to form a plasma in the process chamber 1010 to form a film.

The process chamber 1010 is formed in a cylindrical shape extending in a vertical direction in order to arrange a plurality of substrates W in the vertical direction. For example, the process chamber 1010 includes a cylindrical inner cylinder 1011 that has a flat ceiling but with an open lower end, and a cylindrical outer cylinder 1012 that covers an outside of the inner cylinder 1011 and has a dome-shaped ceiling but with an open lower end. The inner cylinder 1011 and the outer cylinder 1012 are formed of a heat-resistant material such as quartz, and have a double structure in which their axial centers are coaxially arranged. The process chamber 1010 is not limited to a double structure, but may be a single-cylinder structure or a multi-cylinder structure consisting of three or more cylinders.

At a desired circumferential position of the inner cylinder 1011, a housing portion 1013 for housing a gas nozzle 1031 is provided along the vertical direction. An opening 1015 long in the vertical direction is formed on a side wall of the inner cylinder 1011 opposite to the housing portion 1013. The opening 1015 discharges gas in the inner cylinder 1011 to a space between the inner cylinder 1011 and the outer cylinder 1012.

A lower end of the process chamber 1010 is supported by a manifold 1017 of a cylindrical shape and made of stainless steel. A flange 1018 projecting radially outward is formed on an upper end of the manifold 1017. The flange 1018 supports a flange at the lower end of the outer cylinder 1012.

The manifold 1017 includes a support 1020 that is annular and projecting radially inward on an upper inner wall. The support 1020 supports a lower end of the inner cylinder 1011. An opening at a lower end of the manifold 1017 is airtightly closed by a lid 1021 via a sealing member. The lid 1021 is formed into a flat plate made of, for example, stainless steel.

A rotating shaft 1024 for rotatably supporting a wafer boat 1016 passes through a center of the lid 1021 via a magnetic fluid seal 1023. The rotating shaft 1024 rotates around an axis based on a rotational driving force from a drive source and a driving force transmitter that are not illustrated, thereby rotating the wafer boat 1016 around a vertical axis.

The lower portion of the rotating shaft 1024 is supported by an arm of a lifting mechanism 1025 constituted by a boat elevator or the like. The first film-forming apparatus 1 moves up and down integrally with the lid 1021 and the wafer boat 1016 by lifting and lowering the arm of the lifting mechanism 25, thereby inserting and removing the wafer boat 1016 into and from the process chamber 1010.

A rotation plate 1026 is provided at an upper end of the rotating shaft 1024, and the wafer boat 1016 for holding a plurality of substrates W via a heat insulator 1027 is placed on the rotation plate 1026. The wafer boat 1016 holds the substrates W along the horizontal direction at predetermined intervals in the vertical direction.

The gas supply 1030 is inserted into the process chamber 1010 through a manifold 1017. The gas supply 1030 introduces gases such as a processing gas, a purge gas, and a cleaning gas into the inner cylinder 1011. As the processing gas, an appropriate gas is selected in accordance with a type of film to be formed on the substrate W. For example, when a silicon oxide film (SiO₂ film) is to be formed, a silicon-containing gas such as a silane gas can be used as an adsorbing gas. An oxygen-containing gas such as an oxygen (O₂) gas or an ozone (O₃) gas can be used as a reactive gas. Further, an inert gas such as a nitrogen (N₂) gas or an argon (Ar) gas can be used as the purge gas.

The gas supply 1030 includes, for example, a gas nozzle 1031 for introducing the adsorbing gas and the purge gas which are one of the processing gases, and a gas nozzle 1033 for introducing the reactive gas and the purge gas which are the other of the processing gases. The gas supply 30 may be provided with one gas nozzle or three or more gas nozzles.

The gas nozzles 1031 and 1033 are quartz injector tubes that extend along the vertical direction in the inner cylinder 1011 and are bent in an L-shape at their lower ends to penetrate an inside and an outside of the manifold 1017. The gas nozzle 1031 includes a plurality of gas holes 1032 arranged at regular intervals along the vertical direction, and discharge adsorbed gas in the horizontal direction through the gas holes 1032. Similarly, the gas nozzle 1033 includes a plurality of gas holes 1034 arranged at regular intervals along the vertical direction, and discharge reactive gas in the horizontal direction through the gas holes 1034. The gas holes 1032 and 1034 are located, for example, in the middle between the substrates W supported in the vertical direction of the wafer boat 1016. The gas supply 1030 is provided with an opening/closing valve and a flow rate regulator (not illustrated) on the outside of the process chamber 1010 that correspond to each of the gas nozzles 1031 and 1033, and supplies the processing gas into the process chamber 1010 while controlling the flow rate of the processing gas (adsorbing gas and reactive gas).

The gas exhauster 1040 exhausts the gas in the process chamber 1010 to the outside. The gas supplied by the gas supply 1030 flows out from the opening 1015 of the inner cylinder 1011 to a space P1 between the inner cylinder 1011 and the outer cylinder 1012, and is discharged through a gas outlet 1041. A discharge passage 1042 of the gas exhauster 1040 is connected to the gas outlet 1041, and the discharge passage 1042 is provided with a pressure adjusting valve 1043 and a vacuum pump 1044 in the order from upstream to downstream. The gas exhauster 1040 adjusts the pressure (internal pressure) in the process chamber 1010 by suctioning the gas in the process chamber 1010 by the vacuum pump 1044 and adjusting the flow rate of the gas discharged by the pressure adjusting valve 1043.

The heater 1050 is formed in a cylindrical shape covering the periphery of the process chamber 1010, and heats the substrates W in the process chamber 1010 under control of the controller 1080. The heater 1050 may be provided with a mechanism for supplying a cooling gas between the process chamber 1010 and the heater 1050 in order to cool the substrates W in the process chamber 1010.

The controller 1080 may be a computer including a processor 1081, a memory 1082, and an input/output interface (not illustrated). The processor 1081 is a combination of one or more of a central processing unit (CPU), a graphics processing unit (GPU), an application specific integrated circuit (ASIC), a field-programmable gate array (FPGA), a circuit including a plurality of discrete semiconductors, and the like. The memory 1082 includes a main memory including a semiconductor memory and the like, and an auxiliary memory comprising a disk, a semiconductor memory (flash memory), and the like.

The memory 1082 stores a program for operating the first film-forming apparatus 1, a recipe for substrate processing process conditions, and the like. The processor 1081 reads and executes the program in the memory 1082 to control respective configurations of the first film-forming apparatus 1. The controller 1080 may be configured by a host computer or a plurality of client computers that communicate information via a network.

In the first film-forming apparatus 1 described above, each substrate W supported by the wafer boat 1016 is heated by the heater 1050 during film formation. Then, the first film-forming apparatus 1 causes the adsorbing gas to be adsorbed by the surface of the substrate W by supplying the adsorbed gas through the gas nozzle 1031 of the gas supply 1030. Then, a desired film is formed on the substrate W by supplying the reactive gas through the gas nozzle 1033 of the gas supply 1030 and causing the adsorbed gas adsorbed on the surface of the substrate W to react with the reactive gas.

In this type of heat treatment apparatus, temperature changes are more likely to occur on the outer edge side than at the center of the substrate W, and because the adsorbed gas is supplied from the outer edge side of the substrate W, it is sometimes difficult to control the in-plane uniformity of the film thickness. In particular, when the surface of the substrate W includes a projecting and recessed pattern, when the projecting and recessed pattern causes a loading effect in the film formation of the substrate W, it becomes more difficult to control the in-plane uniformity of the film thickness.

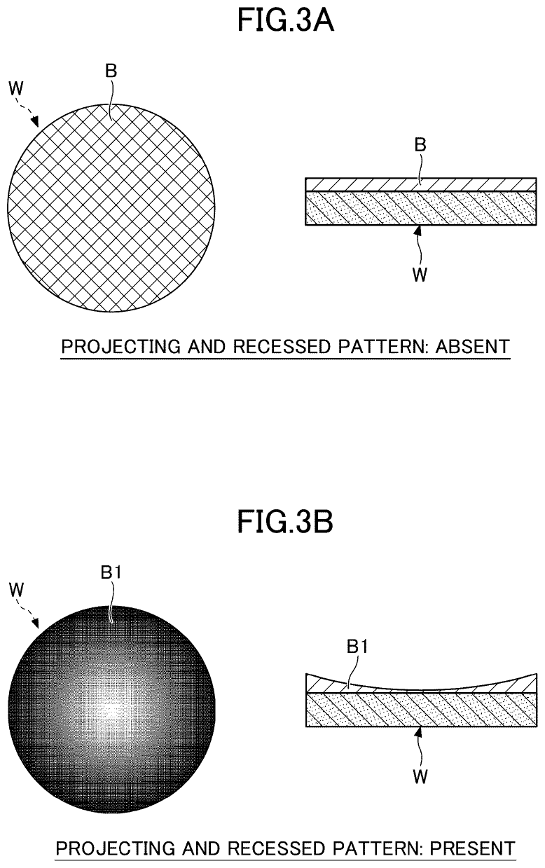

For example, when the substrate W includes no projecting and recessed pattern, a flat film thickness can be formed as illustrated in FIG. 3A by controlling the temperature of the substrate W and the supply of the processing gas in the first film-forming apparatus 1. On the other hand, when the substrate W includes the projecting and recessed pattern, the in-plane uniformity of the film thickness changes as illustrated in FIG. 3B even when the same control is performed as in the case where the projecting and recessed pattern does not exist.

Specifically, when the projecting and recessed pattern exists, the film to be formed tends to have a recessed shape (concave shape) in which the film thickness on the center area of the substrate W is thinner than the film thickness on the outer edge area of the substrate W. When a recessed film thickness is formed in the first film-forming apparatus 1, it is difficult to adjust the film thickness to a flat shape by using the same apparatus. Therefore, the film-forming system SYS moves the substrate W formed in the first film-forming apparatus 1 to the second film-forming apparatus 2, and adjusts the film thickness by the second film-forming apparatus 2.

### Configuration of Second Film-Forming Apparatus 2

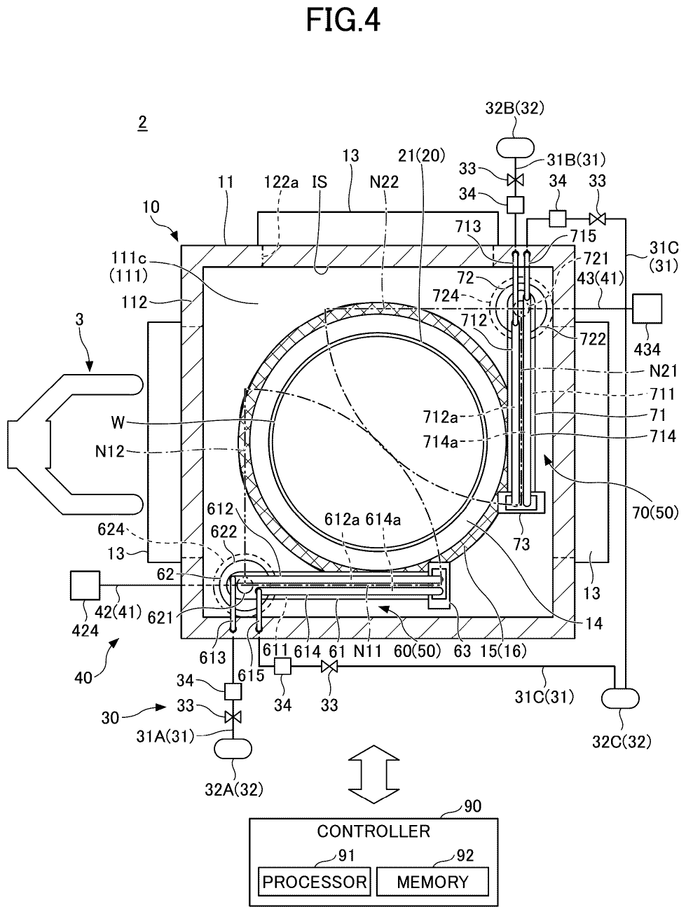

As illustrated in FIG. 4, the second film-forming apparatus 2 is configured as a single-wafer type apparatus for processing the substrate W one by one, and performs film formation by an atomic layer deposition method or a molecular layer deposition method as the substrate processing. Specifically, the second film-forming apparatus 2 includes a process chamber 10, a substrate support 20, a gas supply 30, a gas exhauster 40, and a nozzle gas discharge mechanism 50. The second film-forming apparatus 2 also includes a controller 90 for controlling the operation of each configuration of the second film-forming apparatus 2.

The process chamber 10 is a rectangular box-shaped chamber having an inner space IS capable of housing the substrate W. The size of the process chamber 10 is preferably set in accordance with the size of the substrate W to be processed. For example, when the diameter of the substrate W is 300 mm, the process chamber 10 is formed with each side having a length of from about 400 mm through about 500 mm. No particular limitation is imposed on the shape of the process chamber 10, which may be formed in a cylindrical shape (a circular shape in a plan view).

A gate valve 13 configured to open and close the inner space IS is provided on lateral sides of the process chamber 10. The second film-forming apparatus 2 opens the gate valve before the film formation, and carries the substrate W into the inner space IS from the exterior of the process chamber 10 by a carrier 3 provided in a film-forming system SYS. After the substrate W is carried in, the second film-forming apparatus 2 closes the gate valve 13 and performs the film formation. After completion of the film formation, the second film-forming apparatus 2 opens the gate valve 13, and causes the carrier 3 to enter the inner space IS again and carries the substrate W to the exterior of the process chamber 10. The second film-forming apparatus 2 as illustrated in FIG. 1 includes multiple (three) gate valves 13 and can carry the substrate W into and out of the process chamber 10 from a desired one of the gate valves 13. However, it is enough that the process chamber 10 is provided with at least one gate valve.

As illustrated in FIG. 4, the process chamber 10 includes: a lower recessed chamber 11 that is open on the upper side; and an upper recessed chamber 12 that is open on the lower side. The lower recessed chamber 11 is covered by the upper recessed chamber 12. The lower recessed chamber 11 and the upper recessed chamber 12 are fixed so as to close the openings of each other, thereby forming the inner space IS of the process chamber 10. For the sake of convenience, FIG. 4 illustrates the second film-forming apparatus 2 with the upper recessed chamber 12 being removed.

The lower recessed chamber 11 includes: a bottom wall 111 that is formed in an approximately square shape in a plan view; and an outer edge projection 112 that is slightly projecting from the four outer edges of the bottom wall 111 upward in the vertical direction. The lower recessed chamber 11 includes the substrate support 20 therein. A through hole 111a through which the below-described shaft 22 of the substrate support 20 passes is formed at a center of the bottom wall 111. A center region including the center of the bottom wall 111 is a recessed portion 111b that is recessed downward with respect to an annular region next to the recessed portion 111b. Also, a peripheral base 111c projecting upward of the annular region is formed outward of the annular region of the bottom wall 111 and between the annular region of the bottom wall 111 and the outer edge projection 112.

A temperature controller 14 configured to control the temperature of the substrate W held by the substrate support 20 is disposed in the recessed portion 111b. No particular limitation is imposed on the temperature controller 14, which may have: a configuration including a heater, such as an electric heat wire or the like; a configuration using a flow path that circulates a temperature-controlled medium, which is temperature-controlled by a heat exchanger or the like; or a combined configuration thereof. The temperature controller 14 is connected to the controller 90 via an unillustrated temperature control driver or the like, and the temperature of the substrate W is controlled under the control of the controller 90.

Meanwhile, the upper recessed chamber 12 includes: a ceiling wall 121 that is formed in an approximately square shape (the same shape as the shape of the bottom wall 111) in a plan view; and a side wall 122 that is slightly projecting from the four outer edges of the ceiling wall 121 downward in the vertical direction. The process chamber 10 is fixed such that the lower end of the side wall 122 and the upper end of the outer edge projection 112 face each other. By providing an unillustrated seal member between the lower end of the side wall 122 and the upper end of the outer edge projection 112, the inner space IS is airtightly closed. The gate valve 13 opens and closes, for example, a side opening 122a formed in the side wall 122 (see FIG. 1).

The substrate support 20 provided in the process chamber 10 rotatably holds the substrate W. The substrate support 20 includes: a susceptor 21 configured to directly hold the substrate W; a shaft 22 configured to support the susceptor 21; and a substrate rotator 23 connected to the shaft 22 externally of the process chamber 10.

The susceptor 21 is formed in a regular circular shape that is slightly larger than the substrate W in a plan view. The susceptor 21 includes a stage 21a that extends horizontally in the process chamber 10. An edge is formed around the stage 21a, the edge projecting by the same length as the thickness of the substrate W or by a length greater than the thickness of the substrate W. The substrate support 20 also includes unillustrated multiple lift pin raising and lowering mechanisms configured to receive and deliver the substrate W between the substrate support 20 and the carrier 3. The susceptor 21 may be configured to fix the substrate W by an appropriate holding method (mechanical locking, suctioning, electrostatic chuck, or the like) upon placement of the substrate W on the stage 21a.

The shaft 22 is connected to the lower surface and the center of the susceptor 21, and extends along the axial direction (vertical direction) of the process chamber 10. The substrate rotator 23 rotates the shaft 22 about the axis thereof, thereby rotating the susceptor 21. A magnetic fluid sealing 24 configured to rotatably seal the shaft 22 is provided between the outer peripheral surface of the shaft 22 and the through hole 111a of the bottom wall 111 of the process chamber 10.

The substrate rotator 23 includes an unillustrated motor and an unillustrated driving force transmitter that connects the motor and the shaft 22. The motor of the substrate rotator 23 is connected to the controller 90 via an unillustrated driver. When the motor of the substrate rotator 23 receives power that is adjusted by the driver based on a command of the controller 90, the substrate rotator 23 rotates the shaft 22 at an appropriate rotation speed.

As illustrated in FIGS. 4 and 5, the gas supply 30 includes multiple supply paths 31 that cause processing gases to flow externally of the process chamber 10. The processing gases include processing gases (adsorbing gas, reactive gas), a purge gas, and the like. The processing gas supplied by the gas supply 30 to the process chamber 10 is basically the same gas as the processing gas (adsorbing gas and reactive gas) supplied by the gas supply 1030 in the first film-forming apparatus 1. However, another gas (e.g., changing ozone gas to oxygen gas, etc.) may be selected or other additive gas may be mixed depending on the configuration of the second film-forming apparatus 2, the state of the substrate W, whether or not a plasma is generated, etc. Examples of the plurality of supply paths 31 include an adsorbing gas supply path 31A through which the adsorbing gas flows, a reactive gas supply path 31B through which the reactive gas flows, and a purge gas supply path 31C through which the purge gas flows.

The supply paths 31 include: multiple tanks 32 configured to store gases; multiple opening/closing valves 33 configured to open/close the supply paths 31; and multiple flow rate regulators 34 configured to regulate the flow rates of the gases that are flowing through the flow paths of the supply paths 31. The tanks 32 include an adsorbing gas tank 32A configured to store the adsorbing gas, a reactive gas tank 32B configured to store the reactive gas, and a purge gas tank 32C configured to store the purge gas. Also, each of the opening/closing valves 33 and each of the flow rate regulators 34 are connected to the controller 90 via an appropriate driver. The controller 90 opens the opening/closing valves 33 of the supply paths 31 for predetermined gases at appropriate timings of substrate processing, and regulates the flow rates of the gases by the flow rate regulators 34, thereby supplying the predetermined gases to the process chamber 10.

Meanwhile, the gas exhauster 40 includes multiple exhaust paths 41 that cause gases to flow externally of the process chamber 10, the gases including reacted gas, unreacted gas, purge gas, and the like. Through the respective exhaust paths 41, the gases supplied into the process chamber 10 are exhausted. The exhaust paths 41 are divided into two lines in accordance with the below- described two discharge mechanisms of the nozzle gas discharge mechanism 50, i.e., a first nozzle gas discharge mechanism 60 and a second nozzle gas discharge mechanism 70.

A first exhaust path 42 is connected to the first nozzle gas discharge mechanism 60 and a position in the vicinity thereof. The first exhaust path 42 mainly exhausts the gas discharged from the first nozzle gas discharge mechanism 60. The first exhaust path 42 includes: two or more (two) branched exhaust paths 421; and a merged exhaust path 422 in which the branched exhaust paths 421 are merged and through which the gases are collectively exhausted. One of the branched exhaust paths 421A is directly connected to the first nozzle gas discharge mechanism 60, and exhausts the gas of the first nozzle gas discharge mechanism 60. The branched exhaust path 421A is provided with a pressure adjusting valve 423A configured to adjust the pressure of the gas suctioned in the first nozzle gas discharge mechanism 60.

The other branched exhaust path 421B is connected to the annular region of the bottom wall 111 of the process chamber 10, and exhausts the gas of the inner space IS around the susceptor 21. The bottom wall 111 is provided with an exhaust groove 15 that annularly runs laterally of the temperature controller 14 (see FIG. 4). The branched exhaust path 421B is in communication with the bottom of the exhaust groove 15. In order to uniform a conductance upon exhaustion of the gas in the circumferential direction, an exhaust net 16 is preferably provided at the upper opening of the exhaust groove 15.

In order to suction the gas of the entire first exhaust path 42, a suction mechanism 424 (e.g., a turbomolecular pump, a vacuum pump, or the like) is connected to one end of the merged exhaust path 422. Further, the merged exhaust path 422 is provided with a pressure adjusting valve 423B configured to adjust the pressure of the gas suctioned in the entire first line.

A second exhaust path 43 is connected to the second nozzle gas discharge mechanism 70 and a position in the vicinity thereof. The second exhaust path 43 mainly exhausts the gas discharged from the second nozzle gas discharge mechanism 70. Similar to the first exhaust path 42, the second exhaust path 43 includes: two or more (2) branched exhaust paths 431; and a merged exhaust path 432 in which the branched exhaust paths 431 are merged and through which the gases are collectively exhausted. One of the branched exhaust paths 431A is directly connected to the second nozzle gas discharge mechanism 70, and exhausts the gas of the second nozzle gas discharge mechanism 70. The branched exhaust path 431A is provided partway with a pressure adjusting valve 433A configured to adjust the pressure of the gas suctioned in the second nozzle gas discharge mechanism 70. The other branched exhaust path 431B is connected to the annular region (the bottom of the exhaust groove 15) of the bottom wall 111 of the process chamber 10, and exhausts the gas of the inner space IS around the susceptor 21.

In order to suction the gas of the entire second exhaust path 43, a suction mechanism 434 (e.g., a turbomolecular pump, a vacuum pump, or the like) is connected to one end of the merged exhaust path 432. Further, the merged exhaust path 432 is provided partway with a pressure adjusting valve 433B configured to adjust the pressure of the gas suctioned in the entire second line.

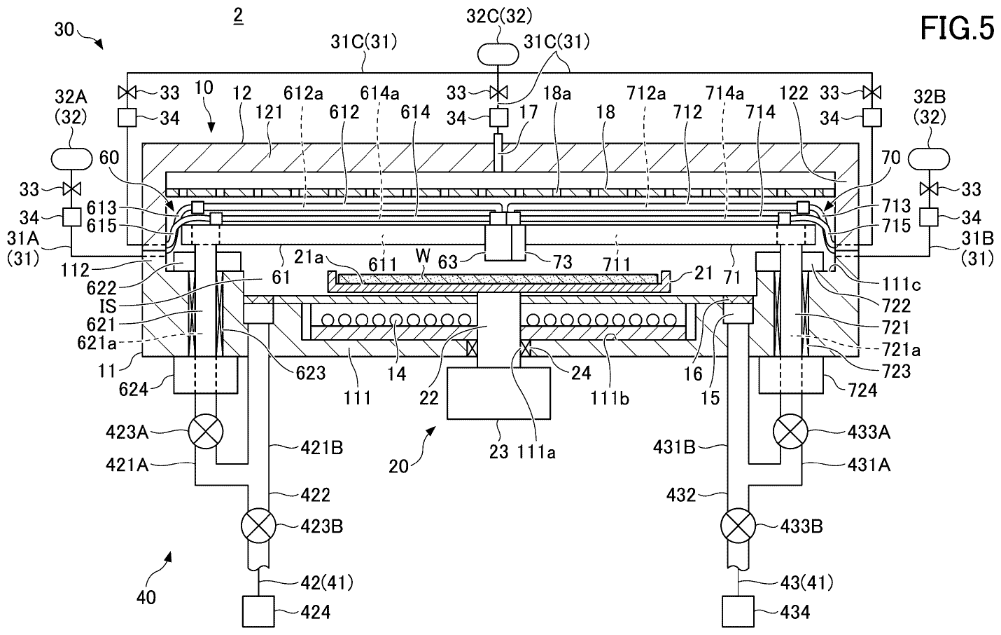

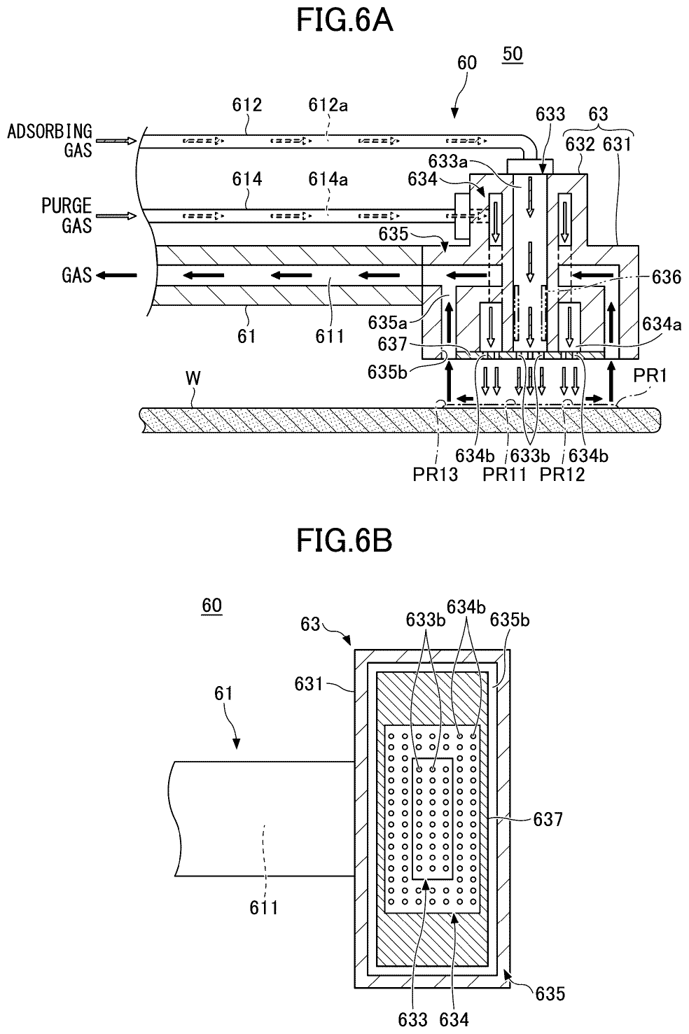

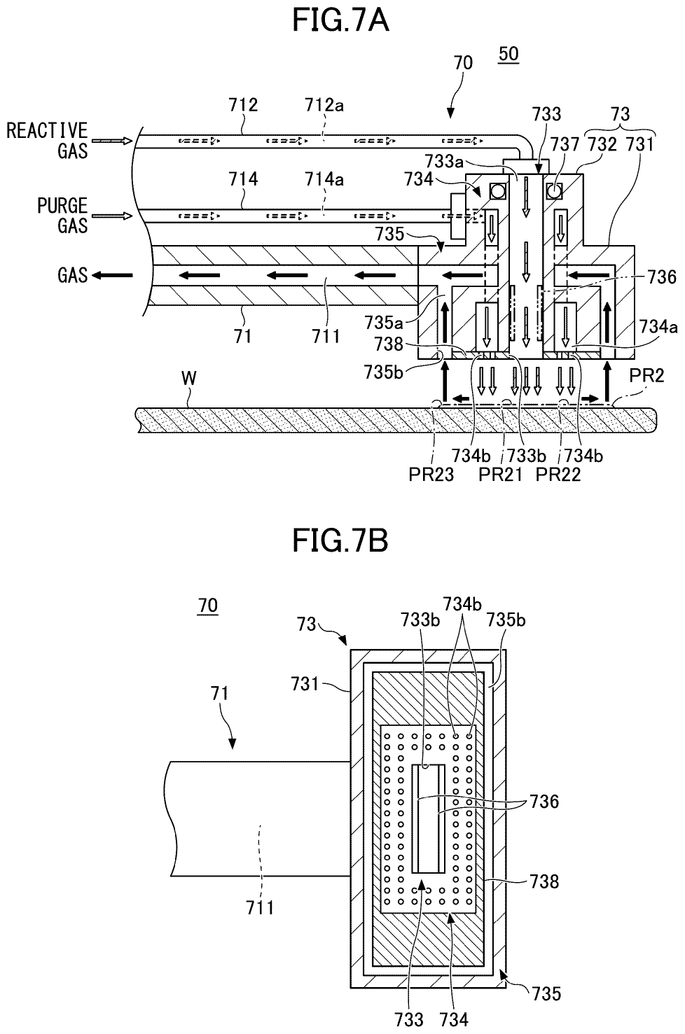

The nozzle gas discharge mechanism 50 has functions of: discharging a processing gas and a purge gas to the front surface (upper surface) of the substrate W held by the susceptor 21 in the process chamber 10; and suctioning the gas above the substrate W. In addition, the nozzle gas discharge mechanism 50 has functions of: discharging a processing gas to the front surface of the substrate W; and suctioning the gas above the substrate W. Therefore, the nozzle gas discharge mechanism 50 includes the first nozzle gas discharge mechanism 60 and the second nozzle gas discharge mechanism 70 in accordance with the type of processing gases (adsorbing gas, the reactive gas) supplied to the substrate W. The second film-forming apparatus 2 swings the first nozzle gas discharge mechanism 60 and the second nozzle gas discharge mechanism 70 relative to the substrate support 20 in the process chamber 10. Thereby, a first processing point region PR1 (see FIG. 6A), where gases are discharged and suctioned in the first nozzle gas discharge mechanism 60, and a second processing point region PR2 (see FIG. 7A), where gases are discharged and suctioned in the second nozzle gas discharge mechanism 70 move independently of each other.

The first nozzle gas discharge mechanism 60 is disposed at one corner (the lower-left corner in FIG. 4) of the four corners of the process chamber 10 (the lower recessed chamber 11). The first nozzle gas discharge mechanism 60 discharges the adsorbing gas and the purge gas and suctions the discharged gases. Specifically, the first nozzle gas discharge mechanism 60 includes: a first nozzle 61; a first nozzle driver 62 provided at the base end of the first nozzle 61; and a first head 63 provided at the projecting end (front end) of the first nozzle 61.

The first nozzle 61 is disposed at the peripheral base 111c of the bottom wall 111, and extends in parallel (horizontally) to the stage 21a of the susceptor 21 at a position that is higher than the substrate W placed on the susceptor 21. The first nozzle 61 is formed in a length that can extend from the first nozzle driver 62 in the process chamber 10 to the center of the process chamber 10. The center of the process chamber 10 coincides with the center of the susceptor 21 (substrate W) and the first nozzle 61 extends to the center of the susceptor 21. That is, the extended length of the first nozzle 61 is set to be slightly shorter than half the diagonal line of the process chamber 10, and is set to be longer than the radius of the susceptor 21.

The first nozzle 61 is formed, for example, in a rectangular cylinder in a cross-sectional view, and has a flow path 611 therein through which the gas can flow. Also, multiple tubes 612 and 614 are provided at appropriate positions (e.g., the upper surface) on the outer peripheral surface of the first nozzle 61 in the process chamber 10. The tubes 612 and 614 extend from the base of the first nozzle 61 to the first head 63 of the first nozzle 61 in parallel to the extending direction of the first nozzle 61.

The tube 612 has a flow path 612a therein extending along the axial direction thereof. The base end of the tube 612 is connected to a connection tube 613 provided in the process chamber 10. The connection tube 613 has appropriate flexibility such that the tube 612 can move in conformity to the rotation of the first nozzle 61. The connection tube 613 is connected to the adsorbing gas supply path 31A externally of the process chamber 10 via a connector provided in the process chamber 10. Thus, the tube 612 can deliver the adsorbing gas from the base end to the first head 63 along the flow path 612a.

The tube 614 has a flow path 614a extending along the axial direction thereof. The base end of the tube 614 is connected to a connection tube 615 provided in the process chamber 10. The connection tube 615 has appropriate flexibility such that the tube 614 can move in conformity to the rotation of the first nozzle 61. The connection tube 615 is connected to the purge gas supply path 31C externally of the process chamber 10 via a connector provided in the process chamber 10. Thus, the tube 614 can deliver the purge gas from the base end to the first head 63 along the flow path 614a.

The flow path 611 of the first nozzle 61 has a cross-sectional flow path area that is larger than that of the flow path 612a of the tube 612 and that of the flow path 614a of the tube 614. The flow path 611 delivers the gas suctioned at the outer periphery of the first head 63, and exhausts the gas to the branched exhaust path 421A via a support shaft 621. The base end of the first nozzle 61 is connected to the support shaft 621 of the first nozzle driver 62. In accordance with the movement of the support shaft 621, the first nozzle 61 and the first head 63 are caused to swing (to repeatedly move) in the form of an arc, with the support shaft 621 being a swing axis.

The first nozzle driver 62 rotates the support shaft 621 while ensuring the flow of the gas through the flow path 611 of the first nozzle 61. To do this, the first nozzle driver 62 includes a cover 622, a magnetic fluid sealing 623, and a drive body 624, in addition to the support shaft 621.

The support shaft 621 extends in the vertical direction and is formed into a circular hard tube having a flow path 621a therein. The upper end of the support shaft 621 firmly fixes the first nozzle 61, extending in the horizontal direction, using an appropriate fixing member. The lower end of the support shaft 621 is connected to the branched exhaust path 421A externally of the process chamber 10 via an unillustrated connector provided in the process chamber 10. Thereby, the first nozzle 61 can suction the gases from the branched exhaust path 421A, the flow path 621a, and the flow path 611 in this order by applying a suction force (negative pressure) to the first head 63 provided at the front end of the first nozzle 61.

The magnetic fluid sealing 623 airtightly seals the space between the bottom wall 111 and the support shaft 621, thereby preventing leakage of the gas from the interior of the process chamber 10 through the first nozzle driver 62. The drive body 624 includes an unillustrated rotary motor and an unillustrated driving force transmitter, and is configured to rotate the support shaft 621 over a set angle range in response to rotary driving of the rotary motor. As the support shaft 621 rotates, the first nozzle 61 swings, with the base end connected to the support shaft 621 being a swing axis. The drive body 624 is connected to the controller 90 via an unillustrated driver, and the rotation speed, rotation direction, and the like of the rotary motor are controlled under the control of the controller 90.

The first nozzle driver 62 is controlled to repeat clockwise rotation as illustrated in FIG. 4 and counterclockwise rotation as illustrated in FIG. 4 over an approximately 90-degree range. By the driving of the first nozzle driver 62, the first nozzle 61 swings between: one first nozzle movement end N11 set near one side of the process chamber 10; and the other first nozzle movement end N12 set near the other side continuous with and orthogonal to the one side of the process chamber 10. The one first nozzle movement end N11 and the other first nozzle movement end N12 are at positions having an appropriate gap from the susceptor 21 in the horizontal direction (i.e., at positions not overlapping with the susceptor 21 in the vertical direction).

As illustrated in FIGS. 4A and 4B, the first head 63 provided at the front end of the first nozzle 61 is formed, in a plan view, in a rectangular shape that is longer in a direction orthogonal to the extending direction of the first nozzle 61. The first head 63 forms the first processing point region PR1, where during the substrate processing, the adsorbing gas is discharged to the substrate W, the purge gas is discharged to the substrate W around the adsorbing gas, and the gas is suctioned externally of the dischargers for the adsorbing gas and the purge gas. The first head 63 is caused to repeatedly move along a first arc path in accordance with swing of the first nozzle 61 between the one first nozzle movement end N11 and the other first nozzle movement end N12. During this movement, the first head 63 faces the substrate W (see FIG. 4).

Specifically, the first head 63 includes: a rectangular head body 631 that is longer in the tangential direction of the first arc path; and a projection 632 projecting from the top surface of the head body 631. The first nozzle 61 is directly connected to the head body 631, and the tube 612 and the tube 614 as described above are connected to the projection 632. The first head 63 includes a processing gas discharger 633, configured to discharge the adsorbing gas, at the center of the head body 631 and at the center of the projection 632.

The processing gas discharger 633 is enclosed by: an inner wall extending over the head body 631 and the projection 632; and a bottom wall (discharge plate 637) facing the substrate W of the head body 631. The processing gas discharger 633 has a discharge path 633a therein, and has multiple discharge holes 633b that are in communication with the discharge path 633a at the bottom wall. The tube 612 is connected to the projection 632 such that the discharge path 633a and the flow path 612a communicate with each other. The processing gas discharger 633 may include, in the discharge path 633a, a heater 636 configured to heat the adsorbing gas supplied from the flow path 612a.

The discharge holes 633b of the processing gas discharger 633 are arranged in a matrix and, as a whole, form a rectangular shape that is longer in the tangential direction of the first arc path. Thereby, the processing gas discharger 633 forms a rectangular adsorbing gas discharge region PR11 at the center of the first processing point region PR1. That is, during the substrate processing, the processing gas discharger 633 can apply the adsorbing gas to a sufficiently small range of the area of the entire substrate W.

Further, the first head 63 includes a purge gas discharger 634, configured to discharge the purge gas, around the processing gas discharger 633. The purge gas discharger 634 is enclosed: between an inner wall and an outer wall of the projection 632; between an inner wall and a partition wall of the head body 631; and by the bottom wall. The purge gas discharger 634 has a discharge path 634a therein, and has multiple discharge holes 634b that are in communication with the discharge path 634a at the bottom wall. The tube 614 is connected to the projection 632 such that the discharge path 634a and the flow path 614a communicate with each other.

Similar to the discharge holes 633b, the discharge holes 634b of the purge gas discharger 634 are arranged in a matrix, and form a rectangularly annular shape around the discharge holes 633b of the processing gas discharger 633. Thereby, the purge gas discharger 634 forms a rectangularly annular purge gas discharge region PR12 externally of the adsorbing gas discharge region. The purge gas discharger 634 prevents the discharge of the purge gas from spreading outward the adsorbing gas discharged by the processing gas discharger 633 during the film formation.

The first head 63 includes a gas suction section 635, configured to suction the gas, around the purge gas discharger 634. The gas suction section 635 is enclosed by the partition wall and an outer wall of the head body 631. The gas suction section 635 has a suction path 635a therein, and has a continuous opening 635b that is in communication with the suction path 635a. The first nozzle 61 and the head body 631 are connected such that the suction path 635a and the flow path 611 communicate with each other.

The opening 635b is formed in a rectangularly annular shape around the outer periphery of the bottom wall of the head body 631. Thereby, the gas suction section 635 forms a rectangularly annular suction region PR13 externally of the purge gas discharge region. The gas suction section 635 can smoothly suction the adsorbing gas and the purge gas, discharged onto the substrate W, around the discharge region PR12 during the substrate processing.

As illustrated in FIGS. 4 and 5, the second nozzle gas discharge mechanism 70 is disposed at another corner (the upper-right corner in FIG. 1) located at a position diagonal to the first nozzle gas discharge mechanism 60 of the four corners of the process chamber 10. The second nozzle gas discharge mechanism 70 discharges the reactive gas and the purge gas and suctions the discharged gases. Specifically, the second nozzle gas discharge mechanism 70 includes: a second nozzle 71; a second nozzle driver 72 provided at the base end of the second nozzle 71; and a second head 73 provided at the projecting end (front end) of the second nozzle 71.

The second nozzle 71 is basically formed in the same shape as that of the first nozzle 61. That is, a flow path 711 is provided in the second nozzle 71. Also, multiple tubes 712 and 714 are provided at appropriate positions (e.g., the front surface) on the outer peripheral surface of the second nozzle 71. The tube 712 has a flow path 712a therein, and the base end thereof is connected to a connection tube 713 provided in the process chamber 10. The connection tube 713 is connected to the reactive gas supply path 31B provided externally of the process chamber 10. The tube 714 has a flow path 714a therein, and the base end thereof is connected to a connection tube 715 provided in the process chamber 10. The connection tube 715 is connected to the purge gas supply path 31C provided externally of the process chamber 10.

The second nozzle driver 72 is also formed in the same manner as in the first nozzle driver 62. That is, the second nozzle driver 72 includes: a support shaft 721, a cover 722, a magnetic fluid sealing 723, and a drive body 724. The support shaft 721 is formed into a circular hard tube having a flow path 721a therein. The upper end of the support shaft 721 supports the second nozzle 71, and the lower end of the support shaft 721 is connected to a branched exhaust path 431A provided externally of the process chamber 10. Also, the drive body 724 includes an unillustrated rotary motor and an unillustrated driving force transmitter, and is configured to rotate the support shaft 721 over a set angle range in response to rotary driving of the rotary motor. The drive body 724 is connected to the controller 90 via an unillustrated driver, and the rotation speed, rotation direction, and the like of the rotary motor are controlled under the control of the controller 90.

The second nozzle driver 72 is controlled to repeat clockwise rotation and counterclockwise rotation about the support shaft 721 over an approximately 90-degree range. By the driving of the second nozzle driver 72, the second nozzle 71 swings between: one second nozzle movement end N21 set near one side of the process chamber 10; and the other second nozzle movement end N22 set near the other side continuous with and orthogonal to the one side of the process chamber 10. The one second nozzle movement end N21 and the other second nozzle movement end N22 are at positions having an appropriate gap from the susceptor 21 in the horizontal direction (i.e., at positions not overlapping with the susceptor 21 in the vertical direction).

As illustrated in FIGS. 7A and 7B, the second head 73 is basically formed in the same manner as in the first head 63. The second head 73 forms a second processing point region PR2, where during the substrate processing, the reactive gas is discharged to the substrate W, the purge gas is discharged to the substrate W around the reactive gas, and the gas is suctioned externally of the dischargers for the reactive gas and the purge gas. The second head 73 is caused to repeatedly move along a second arc path in accordance with swing of the second nozzle 71 between the one second nozzle movement end N21 and the other second nozzle movement end N22. During this movement, the second head 73 faces the substrate W.

Specifically, the second head 73 includes: a rectangular head body 731 that is longer in the tangential direction of the second arc path; and a projection 732 projecting from the front surface of the head body 731. The tube 712 and the tube 714 are connected to the projection 732. The second head 73 includes a processing gas discharger 733, configured to discharge the reactive gas, at the center of the head body 731 and at the center of the projection 732.

The processing gas discharger 733 is enclosed by: an inner wall extending over the head body 731 and the projection 732; and a bottom wall (discharge plate 738) facing the substrate W of the head body 731. The processing gas discharger 733 has a discharge path 733a therein, and has a discharge hole 733b that is in communication with the discharge path 733a. The tube 712 is connected to the projection 732 such that the discharge path 733a and the flow path 712a communicate with each other. In this embodiment, the discharge hole 733b has a rectangular shape that is continuous in the longitudinal direction thereof. However, this is by no means a limitation. The second head 73 may have multiple discharge holes similar to the first head 63. The processing gas discharger 733 may include, in the discharge path 733a, a heater 736 configured to heat the reactive gas supplied from the flow path 712a.

In addition, the processing gas discharger 733 may discharge the reactive gas as is (or after heating) in accordance with requests for the substrate processing. The processing gas discharger 733 may be configured to discharge the reactive gas after being formed into a plasma. In the following, a specific description will be given of a configuration in which the processing gas discharger 733 discharges the reactive gas after being formed into a plasma. The processing gas discharger 733 includes a plasma antenna 737 around the outer peripheral surface of the inner wall of the projection 732. The antenna 737 is connected to an unillustrated high-frequency power supply provided externally of the process chamber 10 via an unillustrated interconnect. For example, the interconnect extends along the outer peripheral surface of the second nozzle 71. Therefore, during the processing substrate, a high-frequency power is supplied from the high-frequency power supply to the antenna 737 via the interconnect, thereby generating a plasma in the reactive gas flowing through the discharge path 733a.

When the reactive gas is formed into a plasma, the reactive gas for use may be, for example, a gas mixture obtained by appropriately mixing O₂, H₂, NH₃, Ar, N₂, and the like. In addition, in order to form a high-quality oxide film, an O₃-containing purge gas may be supplied as the purge gas in the generation of the plasma. Thereby, upon discharge of the reactive gas, the processing gas discharger 733 can form a reactive (plasma) gas discharge region PR21 at the center of the second processing point region PR2.

Further, the second head 73 includes a purge gas discharger 734, configured to discharge the purge gas, around the processing gas discharger 733. The purge gas discharger 734 can have the same configuration as that of the purge gas discharger 634 of the first head 63. That is, the purge gas discharger 734 has a discharge path 734a and multiple discharge holes 734b, and forms a purge gas discharge region PR22. The second head 73 includes a gas suction section 735, configured to suction the gas, around the purge gas discharger 734. The gas suction section 735 can have the same configuration as that of the gas suction section 635 of the first head 63. That is, the gas suction section 735 has a suction path 735a and an opening 735b, and forms a gas suction region PR23.

As illustrated in FIG. 5, the second film-forming apparatus 2 further includes a mechanism configured to supply the purge gas from the upper part (above the nozzle gas discharge mechanism 50) of the process chamber 10 to the lower inner space IS. For example, the ceiling wall 121 of the upper recessed chamber 12 includes a gas introducing port 17 configured to introduce the purge gas. The gas introducing port 17 is connected to a purge gas tank 32C, storing the purge gas, through the purge gas supply path 31C including the opening/closing valve 33 and the flow rate regulator 34.

A shower head 18 may be provided in the upper recessed chamber 12 in order to horizontally diffuse the purge gas introduced from the gas introducing port 17. The shower head 18 is formed in the form of a flat plate having multiple gas holes 18a. The shower head 18 uniformly discharges the purge gas, supplied to the space between the shower head 18 and the ceiling wall 121, to a space below the shower head 18 (a space including the substrate W and the nozzle gas discharge mechanism 50).

As in the controller 1080 of the first film-forming apparatus 1, a computer including a processor 91, a memory 92, an unillustrated input/output interface, and the like can be applied as the controller 90 configured to control the second film-forming apparatus 2. The memory 92 stores: programs for driving the second film-forming apparatus 2; and recipes, such as process conditions for the substrate processing, and the like. The processor 91 reads and executes the program of the memory 92, and controls the components of the second film-forming apparatus 2. The controller 90 may also be configured by a host computer or multiple client computers that perform information communication via a network.

The controller 90 controls the components of the second film-forming apparatus 2, thereby achieving formation of a desired film on the substrate W held by the substrate support 20. At this time, the controller 90 controls the driving of the first nozzle driver 62 and swings the first nozzle 61 in parallel to the surface of the substrate W, and also controls the driving of the second nozzle driver 72 and swings the second nozzle 71 in parallel to the surface of the substrate W.

As described above, the first head 63 repeatedly moves along the first arc path in accordance with the swing of the first nozzle 61. The second head 73 repeatedly moves along the second arc path in accordance with the swing of the second nozzle 71. The first arc path and the second arc path meet at the center of the susceptor 21 (of the substrate W). For example, the controller 90 controls the swing speed of the first nozzle 61 and the swing speed of the second nozzle 71 so as to be the same, and controls the start timing of the swing of the first nozzle 61 and the start timing of the swing of the second nozzle 71 so as to be different. Thereby, the second film-forming apparatus 2 can avoid interference between the first head 63 and the second head 73, thereby stably and repeatedly performing the repeated movement of the first head 63 and the repeated movement of the second head 73.

The controller 90 performs the repeated movement of the first nozzle gas discharge mechanism 60 and the second nozzle gas discharge mechanism 70, and drives the gas supply 30 and the gas exhauster 40, thereby performing supply of the processing gas (adsorbing gas, reactive gas) and suction of the gas using the nozzle gas discharge mechanism 50.

The discharge holes 633b of the first head 63 move along the first arc path, and form the adsorbing gas discharge region PR11 on the lower side in the vertical direction as illustrated in FIG. 6A, thereby adsorbing the adsorbing gas onto the rotating substrate W. Further, by forming the purge gas discharge region PR12 around the adsorbing gas discharge region PR11, the first head 63 can prevent spread of the adsorbing gas and readily control the adsorbing gas discharge region PR11. Then, by suctioning the gas in the suction region PR13 external of the discharge region PR12, the first head 63 can reduce the adsorbing gas remaining near the upper surface of the substrate W, and can prevent adhesion of the adsorbing gas to a region other than the first processing point region PR1 of the substrate W.

Meanwhile, the discharge hole 733b of the second head 73 moves along the second arc path, and forms the reactive gas discharge region PR21 on the lower side in the vertical direction as illustrated in FIG. 7A, thereby discharging the reactive gas, formed into a plasma, onto the rotating substrate W. Further, by forming the purge gas discharge region PR22 around the reactive gas discharge region PR21, the second head 73 can prevent spread of the reactive gas and readily control the reactive gas discharge region PR21. Then, by suctioning the gas in the suction region PR23 external of the discharge region PR22, the second head 73 can reduce the reactive gas remaining near the front surface of the substrate W, and can prevent reaction of the reactive gas in a region other than the second processing point region PR2 of the substrate W.

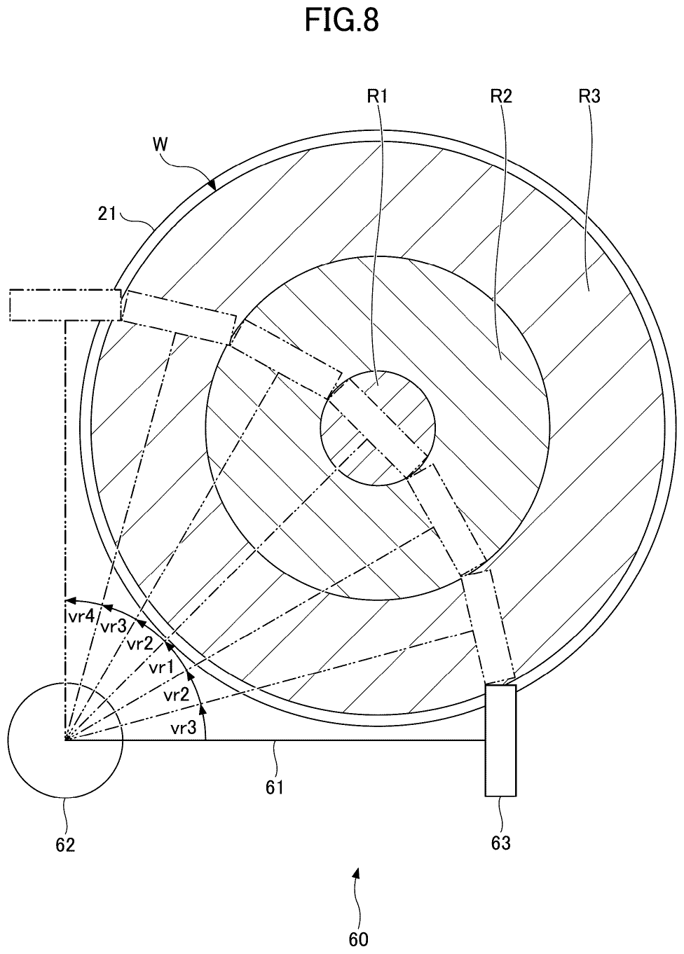

As illustrated in FIG. 8, the second film-forming apparatus 2 may perform control of changing the speed of movement of the first nozzle gas discharge mechanism 60 and the speed of movement of the second nozzle gas discharge mechanism 70. In the following, the swing of the first nozzle gas discharge mechanism 60 will be described, and description of the second nozzle gas discharge mechanism 70 swinging in the same manner will be omitted.

When the surface of the substrate W is divided into multiple sections so as to have equally divided radii from the center of the substrate W in a radial outward direction, the surface areas of the sections are smaller at a center area and are larger on the outer edge area. In FIG. 8, the surface of the substrate W is divided into three sections (hereinafter the divided sections may also be referred to as a first section R1 to a third section R3 in the order from the center to the outer edge of the substrate W). The number of the divided sections is not limited to three, and may be two or may be four or more.

The first section R1 has a regular circular shape at the center of the substrate W. The second section R2 is externally next to the first section R1 and has an annular shape around the first section R1. The third section R3 is externally next to the second section R2 and has an annular shape around the second section R2. In this case, a relation between the surface areas of the sections is as follows: the first section R1<the second section R2<the third section R3. Therefore, the film-forming method can attempt to ensure in-plane uniformity in the film formation by supplying a large amount of the processing gas toward the third section R3 of the rotating substrate W and a small amount of the processing gas toward the first section R1 of the rotating substrate W.

Specifically, the controller 90 increases the supply amount of the processing gas in the third section R3 by making the discharge holes 633b and 733b of the nozzle gas discharge mechanism 50 face the third section R3 (outer edge area) longer than the first section R1 (center area). That is, the controller 90 controls the swing operations of the first nozzle gas discharge mechanism 60 and the second nozzle gas discharge mechanism 70 by setting a moving speed Vr1 of the first section R1>a moving speed Vr2 of the second section R2>a moving speed Vr3 of the third section R3. Thus, the film thickness of the film to be formed on the surface of the substrate W can be appropriately adjusted.

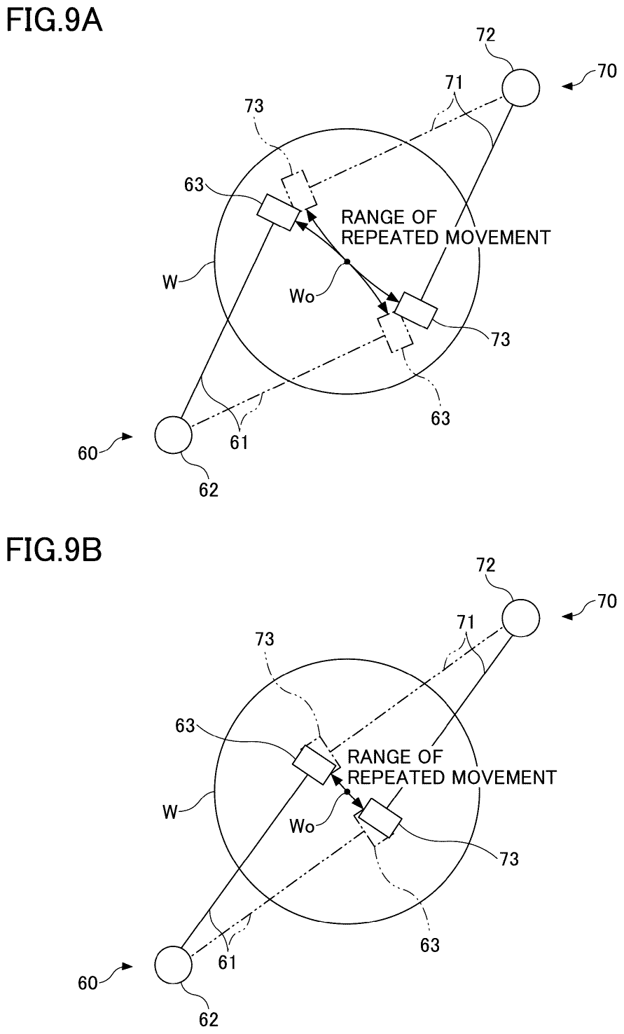

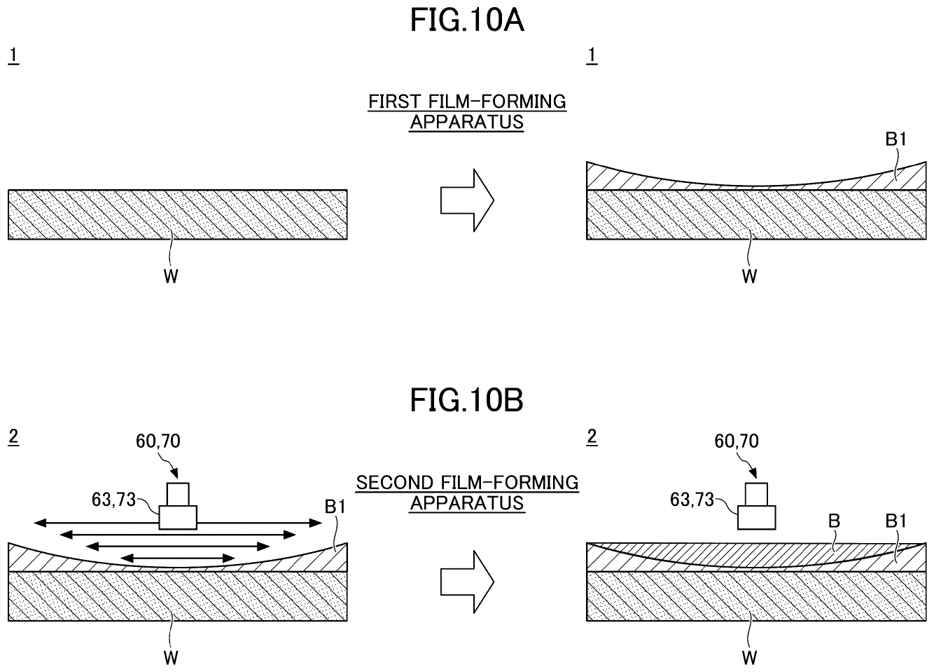

However, in the state where the film is formed in the first film-forming apparatus 1 as described above, the substrate W may have a recessed film B1 as illustrated in FIG. 3B. Therefore, the second film-forming apparatus 2 limits the maximum movement (first nozzle movement end N11, first nozzle movement end N12, second nozzle movement end N21, and second nozzle movement end N22) of the respective movement ranges of the first nozzle gas discharge mechanism 60 and the second nozzle gas discharge mechanism 70 to adjust the film thickness on the substrate W. The movement ranges of the first nozzle gas discharge mechanism 60 and the second nozzle gas discharge mechanism 70 will be described below with reference to FIGS. 9A to 10B.

As illustrated in FIG. 9A, the second film-forming apparatus 2 is configured to repeatedly move the first nozzle gas discharge mechanism 60 and the second nozzle gas discharge mechanism 70 in a movement range that is near the center of the substrate and not reaching the outer edge of the substrate W under the control of the controller 90. In FIG. 9A, the first head 63 and the second head 73 are in contact with each other at a center position Wo of the substrate W, but the controller 90 prevents interference by changing the operation timing of one from another.

In other words, the movement ranges of the first nozzle gas discharge mechanism 60 and the second nozzle gas discharge mechanism 70 are set to be smaller than the diameter of the substrate W. As a result, the first nozzle gas discharge mechanism 60 and the second nozzle gas discharge mechanism 70 can reduce the film-forming amount on the outer edge area of the substrate W (or set the film-forming amount to zero) and increase the film-forming amount on the center area of the substrate W. Hereinafter, the film formation in which the ranges of the movement of first nozzle gas discharge mechanism 60 and the second nozzle gas discharge mechanism 70 are limited is also referred to as a partial film formation.

In the partial film formation, the discharge holes 633b of the first nozzle gas discharge mechanism 60 and the discharge hole 733b of the second nozzle gas discharge mechanism 70 face the substrate W longer for discharge for a portion where the film thickness of the film is less than the film thickness of the target shape. Thus, a large amount of processing gas can be supplied to the portion where the film thickness is insufficient, and the film thickness can be increased. On the other hand, the first nozzle gas discharge mechanism 60 and the second nozzle gas discharge mechanism 70 do not face (or only face for a short time) the substrate W for a portion where the film on the substrate W is thick, so that an increase in the film thickness can be suppressed. Even in the case where the partial film formation is performed, the swing speed of the first nozzle 61 and the swing speed of the second nozzle 71 may be changed for each of a plurality of sections on the substrate W.

In particular, the controller 90 may move the ends of the repeated movement of the first nozzle gas discharge mechanism 60 and the second nozzle gas discharge mechanism 70 toward the center area with an elapse of time in the partial film formation. FIG. 9B illustrates an example in which the range of the movement of the first nozzle gas discharge mechanism 60 and the range of the movement of the second nozzle gas discharge mechanism 70 are narrowed to approximately ½ of the range of movement illustrated in FIG. 9A. Thus, for example, the second film-forming apparatus 2 can gradually increase the film thickness toward the center area of the substrate W without substantially changing the thickness of the film on the outer edge area of the substrate W.

By performing the partial film formation described above, even when the recessed film B1 is formed in the film formation of the first film-forming apparatus 1, the second film-forming apparatus 2 can adjust the film to a flat film B having a uniform film thickness. Hereinafter, the film formation in which the film is formed on the entire surface of the substrate W in the first film-forming apparatus 1 is also referred to as the overall film formation.

Specifically, the first film-forming apparatus 1 supports the plurality of substrates W by means of the wafer boat 1016 inside the process chamber 1010, and supplies processing gas from the gas nozzles 1031 and 1033 to perform the overall film formation for forming a film on the entire surface of each substrate W (see FIG. 2). By this overall film formation, as illustrated in FIG. 10A, the recessed film B1 may be formed on the surface of the substrate W.

Therefore, as illustrated in a left diagram of FIG. 10B, the second film-forming apparatus 2 performs partial film formation after the overall film formation to increase the film thickness at a portion where the film thickness is thin. The second film-forming apparatus 2 sets the movement ranges of the repeated movement of the first head 63 and the second head 73 to ranges that pass through the center of the substrate W but do not reach the outer edge of the substrate W as the discharge condition of the processing gas for the partial film formation. Further, the second film-forming apparatus 2 gradually narrows the movement ranges of the repeated movement of the first head 63 and the second head 73 to the center area as time elapses.

The time (discharge condition) during which the discharge holes 633b of the first head 63 and the discharge hole 733b of the second head 73 face the substrate W can be set, for example, in accordance with the difference in the film thickness between the substrate W without the projecting and recessed pattern and the substrate W with the projecting and recessed pattern. As one example, when the film thickness on the outer edge area obtained by processing the substrate W with the projecting and recessed pattern becomes smaller due to the loading effect, the rotation speed of the substrate support 20 and the speed of movement of the nozzle gas discharge mechanism 50 may be calculated from the difference in the film thickness, and control may be performed in accordance with the calculation result. The surface area of the substrate W may vary with the film thickness of the film formed on the projecting and recessed pattern in the actual overall film formation, and the calculation result may differ from the previous calculation result. Therefore, additional number of cycles and the range of the movement may be determined by monitoring the actual state of the film formed on the substrate W. By repeatedly performing this several times, the second film-forming apparatus 2 can eventually set the discharge condition for forming a film having a desired film thickness and an excellent in-plane uniformity.

Thereby, as illustrated in the right figure of FIG. 10A, the second film-forming apparatus 2 can increase the film thickness of the film on the center area through the film formation compared to that of the recessed film formed through the overall film formation. As a result, the second film-forming apparatus 2 can achieve desired adjustment of the film thickness of the film formed on the substrate W by performing the partial film formation. Accordingly, the second film-forming apparatus 2 can achieve a flat film of a uniform thickness even on a substrate W having the projecting and recessed pattern.

### Film-Forming Method

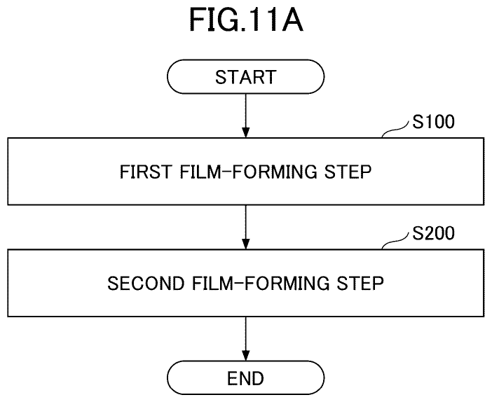

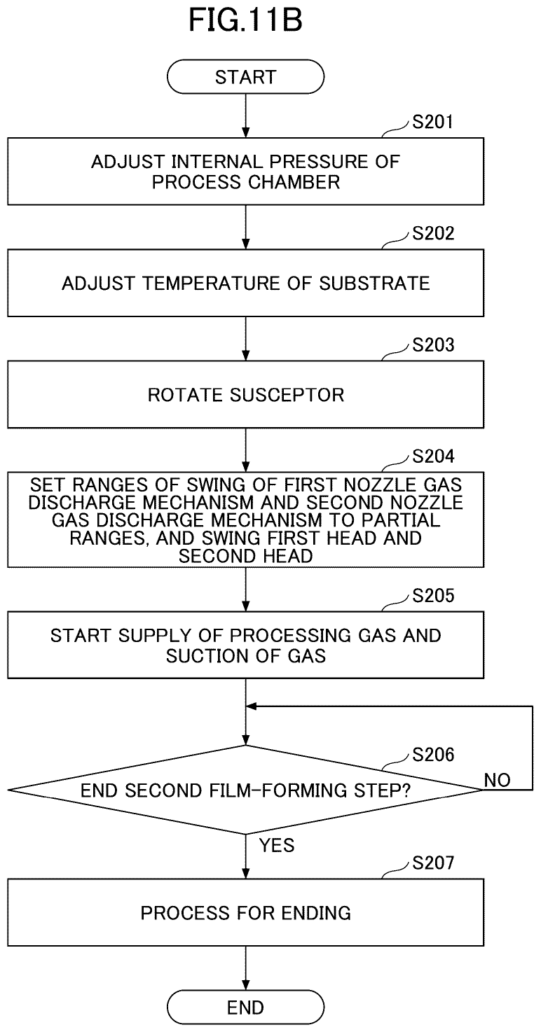

In the following, a film-forming method according to the above embodiment will be described with reference to the flowchart illustrated in FIGS. 11A and 11B. According to the film-forming method, as illustrated in FIG. 11A, after a step of overall film formation, a first film-forming step (step S100), is performed by the first film-forming apparatus 1, and the second film-forming step (step S200), which is the partial film formation, is performed by the second film-forming apparatus 2.

In the first film-forming step, the plurality of substrates W are accommodated in the process chamber 1010 of the first film-forming apparatus 1, and a film is formed on each substrate W by heating each substrate W and supplying a processing gas into the process chamber 1010 (see FIG. 2). As a result, the film to be formed on the surface of the substrate W is formed into a recessed shape that is thin on the central area and thick on the outer edge area, as illustrated in the right diagram of FIG. 10A. Therefore, the film-forming system SYS carries the substrate W after the film is formed in the first film-forming apparatus 1 to the second film-forming apparatus 2 to perform the second film-forming step. When the film-forming system SYS carries the substrate from the first film-forming apparatus 1 to the second film-forming apparatus 2, the discharge conditions (swing speed, a supply amount of the processing gas, the number of round trips, a target time length, etc.) of the processing gas of the second film-forming apparatus 2 may be set by measuring the film thickness of the substrate W by using a measuring device.

The second film-forming apparatus 2 performs, under the control of the controller 90, steps S201 to S207 illustrated in FIG. 11B. After the controller 90 places the substrate W on the susceptor 21 of the substrate support 20, the controller 90 first adjusts the internal pressure of the process chamber 10 to a target pressure (step S201). At this time, while supplying the purge gas from above the process chamber 10 by means of the gas supply 30, the controller 90 exhausts the internal gas from the gas exhauster 40. Thereby, the controller 90 adjusts the internal pressure of the process chamber 10 to the target pressure that is set, for example, in the range of from 1 Torr through 10 Torr.

Also, the controller 90 drives the temperature controller 14 in the process chamber 10, thereby adjusting the temperature of the substrate W placed on the susceptor 21 to the target temperature (step S202). The controller 90 adjusts the temperature of the substrate W to the target temperature that is set, for example, in the range of from about 100° C. through 800° C.

The controller 90 then operates the substrate rotator 23 of the substrate support 20 to rotate the susceptor 21 at a target speed (step S203). The controller 90 rotates the susceptor 21 at the target speed set within a range of, for example, 10 rpm to 1,000 rpm. As a result, the substrate W held by the susceptor 21 also rotates (spins) with the center thereof being a rotation axis.

When an internal pressure of the process chamber 10, the temperature of the substrate W, the rotation speed of the substrate W, and the like are stabilized, the controller 90 finishes a preliminary preparation and starts the partial film formation process. The controller 90 sets the movement ranges of the first nozzle gas discharge mechanism 60 and the second nozzle gas discharge mechanism 70 to a partial range, and swings the first head 63 and the second head 73 (step S204). Specifically, as illustrated in the left diagram of FIG. 10B, the movement ranges of the first head 63 and the second head 73 are narrowed to a range around the center of the substrate W and not reaching the outer edge of the substrate W. Thus, the first head 63 and the second head 73 swing above the center area of the substrate W. At this time, the controller 90 adjusts the timing of the swing of the first head 63 and the timing of the swing of the second head 73 such that the first head 63 and the second head 73 do not interfere.

Then, the controller 90 drives the gas supply 30 and the gas exhauster 40 together with the operation of the nozzle gas discharge mechanism 50, thereby starting supply of the processing gas (adsorbing gas and reactive gas) by using the nozzle gas discharge mechanism 50 and suction of the gas (step S205). Thereby, adsorbing gas is adsorbed on the surface of the substrate W and reactive gas can be reacted with the absorbing gas. The nozzle gas discharge mechanism 50 can form a film to a recessed region on the center area of the substrate W by the partial film formation. Then, by gradually narrowing the movement ranges of the first head 63 and the second head 73, the controller 90 can preferentially perform film formation for the regions (center area) in which the film thickness of the film formed in the overall film formation is smaller.

The controller 90 monitors whether or not to end the second film-forming step during the second film-forming step (step S206). For example, the controller 90 compares the target time of the second film-forming step set in recipes or the like (or the processing time set in accordance with the target film thickness or the like) with the actual driving time of the nozzle gas discharge mechanism 50, and determines whether or not to end the substrate processing in accordance with the actual driving time reaching the target time. The target time of the second film-forming step can be obtained by previously performing an experiment, simulation, or the like for the substrate W provided with the film formed in the first film-forming step to obtain the length of time required to make the thickness of the film on the surface of the substrate W uniform.

Finally, the controller 90 ends the film-forming method by performing a process for ending of the second film-forming apparatus 2 (step S207). The process for ending includes stopping the driving of the first nozzle gas discharge mechanism 60 and the second nozzle gas discharge mechanism 70, stopping the rotation of the substrate support 20, the supply of the gas by the gas supply 30, the temperature control by the temperature controller 14, and the like. Thereby, the second film-forming apparatus 2 can carry the substrate W out of the process chamber 10.

The film-forming system SYS and the film-forming method according to the present embodiment are not limited to the above-described embodiment, and various modifications can be made. For example, in the film-forming method according to the above-described embodiment, the movement range of the repeated movement of the nozzle gas discharge mechanism 50 is made smaller than the diameter of the substrate W in the second film-forming step. However, the present disclosure is not limited to the above, and the film-forming method may change the discharge conditions such as increasing the time length for which the first nozzle gas discharge mechanism 60 and the second nozzle gas discharge mechanism 70 face the substrate W, or increasing the discharge amount of the processing gas to be supplied to the substrate W for the thin film portion. That is, in the second film-forming step, the operations of the first nozzle gas discharge mechanism 60 and the second nozzle gas discharge mechanism 70, the rotational speed of the substrate W side, and the discharge amount of the processing gas are set so as to compensate film thickness for the thin film portion. Thus, the film-forming method can appropriately adjust the film thickness of the film to be formed on the substrate W.

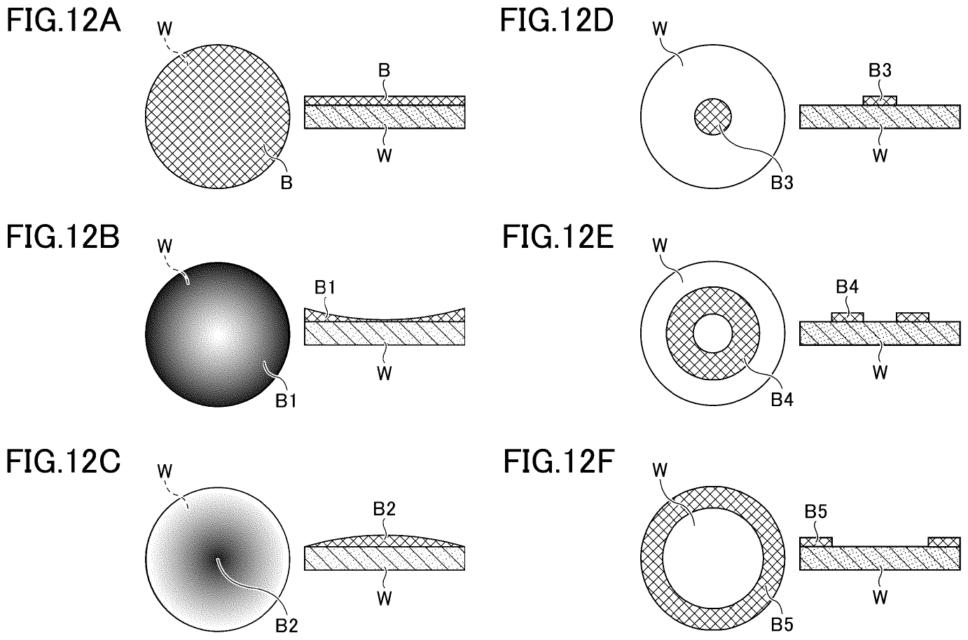

In the above embodiment, as the final target shape of the film to be formed on the surface of the substrate W, the flat film B as illustrated in FIG. 12A has been used as an example. However, the final target shape of the film to be formed on the surface of the substrate W is not limited to a flat shape, and may be set to various shapes as illustrated in FIGS. 12B to 12F.

For example, FIG. 12B illustrates an example in which the target shape is a recessed (concave-shaped) film B1 having a thin film thickness on the center area of the substrate W and a thick film thickness on the outer edge area of the substrate W. FIG. 12C illustrates an example in which the target shape is a chevron film B2 having a thick film thickness on the center area of the substrate W and a thin film thickness on the outer edge area of the substrate W. FIG. 12D illustrates an example in which a circular film B3 is formed as the target shape, on the center area of the substrate W. FIG. 12E illustrates an example in which a film B4 having an annular shape and being arranged at a middle part of the radius of the substrate W in a circular manner is formed as a target shape. FIG. 12F illustrates an example of forming a film B5 annularly surrounding the outer edge of the substrate W as a target shape.

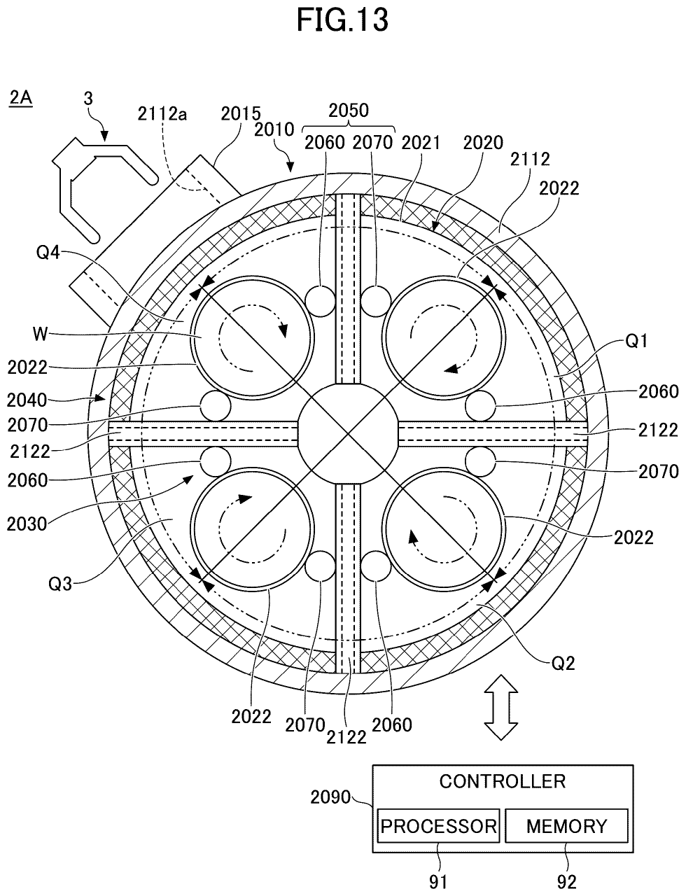

In the second film-forming apparatus 2 according to the above embodiment, the first nozzle gas discharge mechanism 60 and the second nozzle gas discharge mechanism 70 move (swing) relative to the substrate W. In addition, the second film-forming apparatus 2 may have a configuration in which the nozzle for supplying the processing gas is fixed and the substrate support 20 for supporting the substrate W moves relative to the nozzle. FIG. 13 illustrates an example of the second film-forming apparatus 2A in this case.

The second film-forming apparatus 2A according to the modified example illustrated in FIG. 13 includes a process chamber 2010, a substrate support 2020, a gas supply 2030, a gas exhauster 2040, and a nozzle gas discharge mechanism 2050. In FIG. 13, a top plate of the process chamber 2010 is omitted for convenience of explanation.

The process chamber 2010 is formed of quartz or the like, accommodates a plurality of substrates W, and includes an internal space capable of reducing pressure. The process chamber 2010 has a regular circular shape in a plan view and is formed in a cylindrical shape having a vertical length shorter than a diameter in the horizontal direction. The process chamber 2010 includes a side opening 2112a in the side wall 2112 through which the carrier 3 configured to carry the substrate W enters and exits from the process chamber 2010. Additionally, the side wall 2112 is provided with a gate valve 2015 for opening and closing the side opening 2112a.

The substrate support 2020 holds a plurality (four in FIG. 13) of substrates W housed in the process chamber 2010 so as to be able to revolve and rotate. For this purpose, the substrate support 2020 includes a rotation table 2021 and a plurality (four) of tables 2022 for supporting each substrate W on the surface of the outer periphery of the rotation table 2021. The four tables 2022 are provided at the same distance (radial positions) away from the center of the rotation table 2021 and are arranged at equal intervals (i.e. every 90 degrees) along the circumferential direction. The substrate support 2020 repeatedly moves the rotation table 2021 in the circumferential direction. For example, the substrate support 2020 rotates the rotation table 2021 clockwise by 90° in FIG. 13 and then rotates the rotation table 2021 counterclockwise by 90° in FIG. 13.

The gas supply 2030 includes a plurality of supply paths (not illustrated) on the outside of the process chamber 2010 for circulating gases such as processing gases (adsorbing gas and reactive gas) and a purge gas, and supplies the gases into the process chamber 2010 via the respective supply paths. The gas exhauster 2040 includes a plurality of discharge paths (not illustrated) for circulating gases (reacted gas, unreacted gas, purge gas, etc.) outside the process chamber 2010, and discharges the gases supplied into the process chamber 2010 via the respective discharge paths.

The nozzle gas discharge mechanism 2050 is configured to discharge the processing gas and the purge gas to the surface (front surface) of each substrate W at an appropriate position in the process chamber 2010, and suction the gases above the substrate W. The nozzle gas discharge mechanism 2050 includes a first nozzle 2060 for discharging the processing gas and the purge gas, and a second nozzle 2070 for discharging the reactive gas and the purge gas. The process chamber 2010 includes four first nozzles 2060 and four second nozzles 2070.

The first nozzles 2060 and the second nozzles 2070 are fixed to the four partition wall members 2122. For example, each of the partition wall members 2122 holds the first nozzle 2060 on the side surface located counterclockwise in FIG. 13, while holding the second nozzle 2070 on the side surface located clockwise in FIG. 13. In other words, one of the first nozzles 2060 and one of the second nozzles 2070 are disposed in each of the first quadrant Q1 to the fourth quadrant Q4 partitioned by the partition wall members 2122.

Each of the first nozzle 2060 and the second nozzle 2070 is provided so as to penetrate through the top plate of the process chamber 2010, and is connected to the gas supply 2030 and the gas exhauster 2040 on the outside of the process chamber 2010. The first nozzle 2060 and the second nozzle 2070 inside the process chamber 2010 discharge and suction gas toward a lower side in the vertical direction. The configuration of the first nozzle 2060 for discharging and suctioning gas is substantially the same as the configuration of the first head 63 according to the embodiment. The configuration of the second nozzle 2070 for discharging and suctioning gas is substantially the same as the configuration of the second head 73 according to the embodiment. Thus, a first processing point region PR1 (see FIG. 3A also) is formed on the lower side in the vertical direction of the first nozzle 2060, and a second processing point region (see FIG. 4A also) is formed on the lower side in the vertical direction of the second nozzle 2070.

The center of the first nozzle 2060 and the center of the second nozzle 2070 face the center of a mounting table 2022 provided on the rotation table 2021. Thus, the first nozzle 2060 and the second nozzle 2070 pass over the center of and on the vertical upper side of the substrate W placed on each mounting table 2022 as the rotation table 2021 rotates. Since each mounting table 2022 spins during film formation, the first nozzle 2060 and thus the second nozzle 2070 can face the overall surface of the substrate W.

The controller 2090 of the second film-forming apparatus 2A repeatedly moves the rotation table 2021 clockwise and counterclockwise while the tables 2022 are rotated (spun) to perform substrate processing on the substrates W on the tables 2022. That is, in the film-forming method, the substrates W are moved relative to the first nozzle 2060 and the second nozzle 2070 that are fixed, to form a desired film on the surface of the substrate W.

Then, the controller 2090 performs a second film-forming step similar to the processing flow of the film-forming method illustrated in FIG. 10B. That is, in the second film-forming step, the ranges of the clockwise repeated movement and counterclockwise repeated movement of the rotation table 2021 are narrowed to perform a partial film formation on a portion (e.g., center area) of the surface of the substrate W. Thus, the second film-forming apparatus 2A and the film-forming method can appropriately control the film formation such that the film on the surface of the substrate W has a target shape.

The technical ideas and effects of the present disclosure described in the above-described embodiments will be described below.

A first aspect of the present disclosure provides a film-forming method for forming a film on the substrate W. The film-forming method includes: (A) forming the film on the substrate W by the first film-forming apparatus 1, (B) moving the substrate W on which a film is formed in (A) to the second film-forming apparatus 2 or 2A that is different from the first film-forming apparatus 1, and forming a film over the substrate by the second film-forming apparatus 2. In (B), a film thickness of the film formed over the substrate W is adjusted by, in the process chamber 10, rotating the substrate W, moving one of the substrate W or the nozzle gas discharge mechanism 50 relative to another of the substrate W or the nozzle gas discharge mechanism 50 such that the discharge holes 633b and 733b of the nozzle gas discharge mechanism 50 pass over the center of the substrate W, and discharging the gas toward the substrate W from the discharge holes 633b and 733b of the nozzle gas discharge mechanism 50.

According to the above, the film-forming method can readily form the film having a desired film thickness on the substrate W with high accuracy by performing (B) by the second film-forming apparatus 2 or 2A, i.e., adjusting the film thickness of the film formed on the substrate W. That is, even when the film thickness of the film formed in (A) by the first film-forming apparatus 1 is not that of the target shape due to a projecting and recessed pattern formed on the substrate W, the film-forming method can adjust the film thickness in (B) to be closer to that of the target shape. In other words, the film-forming method can perform (A) and (B), thereby performing film formation through desired adjustment of film shapes including the film thickness.

Also, the second film-forming apparatus 2 or 2A uses as the discharge condition in (B), in which the discharge holes 633b and 733b face the substrate W for a longer time, a region in which the film thickness of the film formed in (A) is smaller than the film thickness of the target shape. Thereby, the film-forming method can perform film formation by supplying a larger amount of the processing gas to the region in which the film thickness of the film is smaller than a desired film thickness, and can readily achieve a desired film thickness.

In (B), the movement range for moving one of the substrate W or the nozzle gas discharge mechanism 50 relative to another of the substrate W or the nozzle gas discharge mechanism 50 is made shorter than the diameter of the substrate W. Thus, in the film-forming method, the processing gas can be intensively supplied in the movement range that is narrow, and the partial film thickness of the substrate W can be stably adjusted.

In (B), the movement range for relative movement of the substrate W or the nozzle gas discharge mechanism 50 is gradually narrowed as time elapses. Thus, in the film-forming method, the movement range can be narrowed according to the portion where the film thickness is thin, and the partial film thickness of the substrate W can be more preferably adjusted.

In (B), the movement range for the relative movement of the substrate W or the nozzle gas discharge mechanism 50 is set to a range in which the discharge holes 633b and 733b pass through the center of the substrate W but do not reach the outer edge of the substrate W. Thus, in the second film-forming step, a film having a thin outer edge area of the substrate W and a thick center area of the substrate W can be formed.

In (A), a film is formed in a recessed shape, in which the film thickness on the outer edge area of the substrate W is larger than the film thickness on the center area of the substrate W. In (B), a film is formed such that the film thickness on the center area of the substrate W and the film thickness on the outer edge area of the substrate W are uniform. Thus, for example, even when a film is formed in a recessed shape in (A) due to a substrate having a projecting and recessed pattern on the surface, the film thickness can be accurately adjusted to a flat film thickness in (B).

In (B), the speed at which one of the substrate W or the nozzle gas discharge mechanism 50 is moved relative to another of the substrate W or the nozzle gas discharge mechanism 50 is changed in accordance with the position of the substrate W faced by the discharge holes 633b and 733b. Thereby, for example, the film-forming method can address factors, such as, for example, the surface area increasing toward the outer edge of the substrate W, by changing the speed of the relative movement. This enables further stable film formation for forming a film on the substrate W to have the target shape.

Also, the nozzle gas discharge mechanism 50 includes: the first nozzle gas discharge mechanism 60 and the second nozzle gas discharge mechanism 70 that are configured to discharge the processing gas to the substrate. In (A) and (B), in a state in which the substrate W is being rotated, the first nozzle gas discharge mechanism 60 and the second nozzle gas discharge mechanism 70 are caused to swing independently of each other. Thereby, the film-forming method can supply appropriate processing gas to the substrate W without the first nozzle gas discharge mechanism 60 and the second nozzle gas discharge mechanism 70 interfering.

The first nozzle gas discharge mechanism 60 includes: the first nozzle 61 extending in the process chamber 10; the first nozzle driver 62 provided at the base end of the first nozzle 61 and configured to swing the first nozzle 61; and the first head 63 provided at the front end of the first nozzle 61 and configured to discharge the adsorbing gas as the processing gas. The second nozzle gas discharge mechanism 70 includes: the second nozzle 71 extending in the process chamber 10; the second nozzle driver 72 provided at the base end of the second nozzle 71 and configured to swing the second nozzle 71; and the second head 73 provided at the front end of the second nozzle 71 and configured to discharge, as the processing gas, the reactive gas that is reactive with the adsorbing gas. With the first nozzle gas discharge mechanism 60 and the second nozzle gas discharge mechanism 70, the film-forming method can supply the adsorbing gas and the reactive gas over the substrate W in a pinpointed manner, and can form a desired film with high accuracy.

A second aspect of the present disclosure is a film-forming system SYS including the first film-forming apparatus 1 configured to form a film on a substrate W, and the second film-forming apparatus 2 configured to form a film over the substrate W on which a film is formed in the first film-forming apparatus 1. The second film-forming apparatus 2 includes: the process chamber 10; the substrate support 20 configured to support the substrate W in the process chamber 10 and rotate the substrate W; the nozzle gas discharge mechanism 50 including discharge holes 633b and discharge hole 733b configured to discharge a processing gas toward the substrate W supported by the substrate support 20; and the controller 90 configured to control movements of the substrate support 20 and the nozzle gas discharge mechanism 50. The controller 90 is configured to control: forming the film over the substrate W by, in the process chamber 10, rotating the substrate W, moving one of the substrate W or the nozzle gas discharge mechanism 50 relative to another of the substrate W or the nozzle gas discharge mechanism 50 such that the discharge holes 633b and 733b of the nozzle gas discharge mechanism 50 pass over the center of the substrate W, and discharging the gas toward the substrate W from the discharge holes 633b and 733b; and adjusting a film thickness of the film formed over the substrate W. In this case, the film-forming system SYS can readily form a film to have a desired film thickness with high accuracy.

The film-forming method and the film-forming system SYS according to the embodiment disclosed herein are illustrative in all respects and are not limiting. The embodiments can be modified and improved in various ways without departing from the scope of claims recited and the subject matters thereof. The matters described in the above embodiments can take other configurations to an extent without involving contradiction and may be combined to an extent without involving contradiction.

According to an embodiment, it is possible to readily form a film to have a desired film thickness with high accuracy.

What is claimed is:

1. A film-forming method for forming a film on a substrate, the film-forming method comprising:
(A) forming a film on a substrate by a first film-forming apparatus, and
(B) moving the substrate provided with the film formed in the (A) to a second film-forming apparatus different from the first film-forming apparatus and forming a film over the substrate by the second film-forming apparatus; wherein
in the (B), the substrate is rotated inside a process chamber, one of the substrate or a nozzle gas discharge mechanism is moved relative to another of the substrate or the nozzle gas discharge mechanism such that a discharge hole of the nozzle gas discharge mechanism passes over a center of the substrate, and a processing gas is discharged from the discharge hole toward the substrate, thereby adjusting a film thickness of the film to be formed over the substrate.

2. The film-forming method according to claim 1, wherein
in the second film-forming apparatus, in the (B), a discharge condition of the processing gas is set such that the discharge hole faces, for a longer time, a region in which the film thickness of the film formed in the (A) is thinner than that of a target shape.

3. The film-forming method according to claim 2, wherein
in the (B), a range in which one of the substrate or the nozzle gas discharge mechanism is moved relative to the another of the substrate or the nozzle gas discharge mechanism is set to be shorter than a diameter of the substrate.

4. The film-forming method according to claim 3, wherein
in the (B), the range in which one of the substrate or the nozzle gas discharge mechanism is moved relative to the another of the substrate or the nozzle gas discharge mechanism is gradually narrowed over time.

5. The film-forming method according to claim 2, wherein
in the (B), a range in which one of the substrate or the nozzle gas discharge mechanism is moved relative to the another of the substrate or the nozzle gas discharge mechanism is set to a range in which the discharge hole passes over the center of the substrate and does not reach an outer edge of the substrate.

6. The film-forming method according to claim 1, wherein
in the (A), a film having a recessed shape in which the film thickness on an outer edge area of the substrate is larger than the film thickness on a center area of the substrate is formed, and
in the (B), a film is formed such that the film thickness on the center area of the substrate and the film thickness on the outer edge area of the substrate are uniform.

7. The film-forming method according to claim 1, wherein
in the (B), a speed at which one of the substrate or the nozzle gas discharge mechanism is moved relative to the another of the substrate or the nozzle gas discharge mechanism is changed in accordance with a position of the substrate faced by the discharge hole.

8. The film-forming method according to claim 1, wherein
the nozzle gas discharge mechanism includes
a first nozzle gas discharge mechanism and a second nozzle gas discharge mechanism that are configured to discharge the processing gas to the substrate, and
in the (B), in a state the substrate is being rotated, the first nozzle gas discharge mechanism and the second nozzle gas discharge mechanism are caused to swing independently of each other.

9. The film-forming method according to claim 8, wherein
the first nozzle gas discharge mechanism includes
a first nozzle extending in the process chamber;
a first nozzle driver provided at a base end of the first nozzle and configured to swing the first nozzle, and
a first head provided at a front end of the first nozzle and configured to discharge an adsorbing gas as the processing gas, and
the second nozzle gas discharge mechanism includes
a second nozzle extending in the process chamber,
a second nozzle driver provided at a base end of the second nozzle and configured to swing the second nozzle, and
a second head provided at a front end of the second nozzle and configured to discharge, as the processing gas, a reactive gas that is reactive with the adsorbing gas.

10. A film-forming system, comprising:
a first film-forming apparatus configured to form a film on a substrate;
a second film-forming apparatus that is different from the first film-forming apparatus and configured to form a film over the substrate provided with the film formed in the first film-forming apparatus, wherein
the second film-forming apparatus includes
a process chamber,
a substrate support configured to support the substrate in the process chamber and rotate the substrate,
a nozzle gas discharge mechanism including a discharge hole configured to discharge a processing gas toward the substrate supported by the substrate support, and
a controller including a memory and a processor coupled to the memory,
the processor being configured to
control movements of the substrate support and the nozzle gas discharge mechanism, and
adjust a film thickness of the film formed over the substrate by: rotating the substrate in the process chamber; moving one of the substrate or the nozzle gas discharge mechanism relative to another of the substrate or the nozzle gas discharge mechanism such that the discharge hole of the nozzle gas discharge mechanism passes over a center of the substrate; and discharging the processing gas toward the substrate from the discharge hole.
